(19) United States
(12) Patent Application Publication
(10) Pub. No.: US 2025/0112470 A1
(43) Pub. Date: Apr. 3, 2025

(54) DETECTION OF LOW EFFICIENCY POWER STATES

(71) Applicant: Advanced Micro Devices, Inc., Santa Clara, CA (US)

(72) Inventors: David King Wai Li, Austin, TX (US); Indrani Paul, Austin, TX (US)

(73) Assignee: Advanced Micro Devices, Inc., Santa Clara, CA (US)

(21) Appl. No.: 18/478,346

(22) Filed: Sep. 29, 2023

(51) Int. Cl. H02J 4/00; G01R 19/165

(52) U.S. Cl. CPC H02J 4/00; G01R 19/16571

(57) ABSTRACT

The disclosed device includes power circuits that can communicate with a control circuit. In response to a power circuit communicating a low efficiency state, the control circuit can redistribute at least a portion of a load of the power circuit to one or more other power circuits. Various other methods, systems, and computer-readable media are also disclosed.

### BACKGROUND

Computing devices can have multiple power sources, such as battery, plugged in, etc., and use various voltage regulators and other power circuits for delivering power from the power sources to components as needed. For example, voltage regulators can convert supplied voltages to appropriate voltage rails for the components. Based on processing workloads and power states of the components, the actual loads for the voltage regulators can vary. However, certain conditions can lead to low efficiency power states for the voltage regulators.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a block diagram of an exemplary system for detecting low efficiency power states.

FIG. 2 is a block diagram of an exemplary power delivery network for communicating when low efficiency power states are detected.

FIG. 3 is a flow diagram of an exemplary method for detecting and responding to low efficiency power states.

FIG. 4 is a flow diagram of another exemplary method for detecting and responding to low efficiency power states.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to detecting low efficiency states for power circuits. As will be explained in greater detail below, implementations of the present disclosure include communicating a low efficiency state of a power circuit, and in response to the indication, redistributing a load of the power circuit to other power circuits. By communicating the low efficiency states, the systems and methods described herein can dynamically respond and redistribute loads to improve power efficiency.

In one implementation, a device for detecting low efficiency power states includes a control circuit configured to receive, from a first power circuit of a plurality of power circuits, an indication that the first power circuit is in a low efficiency state, and redistribute, in response to the indication, at least a portion of a load of the first power circuit to a second power circuit of the plurality of power circuits.

In some examples, the indication is in response to detecting the load exceeding an upper load threshold. In some examples, the control circuit is configured to redistribute at least the portion of the load of the first power circuit by selecting the second power circuit based on matching voltage rails with the first power circuit, enabling the second power circuit, and switching at least the portion of the load of the first power circuit to the second power circuit.

In some examples, the control circuit is further configured to select the second power circuit from disabled power circuits of the plurality of power circuits. In some examples, the first power circuit corresponds to an always-on power circuit configured to communicate with the control circuit. In some examples, the upper load threshold is dynamically determined. In some examples, the upper load threshold is predetermined.

In some examples, the indication is in response to a current output of the first power circuit falling below a current threshold. In some examples, the control circuit is configured to redistribute at least the portion of the load of the first circuit by switching the load of the first power circuit to the second power circuit, and disabling the first power circuit.

In one implementation, a system for detecting low efficiency power states includes a plurality of power circuits and a control circuit configured to receive, from a first power circuit of the plurality of power circuits, an indication that the first power circuit is in a low efficiency state, select a second power circuit of the plurality of power circuits, and switch at least a portion of a load of the first power circuit to the second power circuit.

In some examples, the control circuit is configured to select the second power circuit based on matching voltage rails of the first and second power circuits. In some examples, the system includes at least one switch for switching the load between the first and second power circuits. In some examples, the at least one switch corresponds to a multiplexer.

In some examples, the first power circuit is configured to send the indication in response to detecting the load exceeding an upper load threshold. In some examples, the control circuit is configured to select the second power circuit from disabled power circuits of the plurality of power circuits, and enable the second power circuit. In some examples, the upper load threshold is dynamically determined. In some examples, the upper load threshold is predetermined.

In some examples, the first power circuit is configured to send the indication in response to detecting that a current output of the first power circuit is below a current threshold. In some examples, the control circuit is further configured to switch the load of the first power circuit to the second power circuit, and disable the first power circuit. In some examples, the current threshold is dynamically determined or predetermined

In one implementation, a method for detecting low efficiency power states include (i) detecting a first power circuit of a plurality of power circuits having a first load below a lower load threshold, (ii) consolidating loads of the plurality of power circuits such that the first power circuit is uncoupled from the first load, (iii) disabling the first power circuit, (iv) receiving an indication from a second power circuit of the plurality of power circuits that a second load of the second power circuit exceeds an upper load threshold, (v) selecting a third power circuit from disabled power circuits of the plurality of power circuits, (vi) enabling the selected third power circuit, and (vii) switching at least a portion of the second load from the second power circuit to the third power circuit.

In some examples, consolidating the plurality of power circuits includes selecting, from the plurality of power circuits, a fourth power circuit based on matching voltage rails with the first power circuit, and switching the first load from the first circuit to the selected fourth power circuit. In some examples, selecting the third power circuit is based on matching voltage rails with the second power circuit.

Features from any of the implementations described herein can be used in combination with one another in accordance with the general principles described herein. These and other implementations, features, and advantages will be more fully understood upon reading the following detailed description in conjunction with the accompanying drawings and claims.

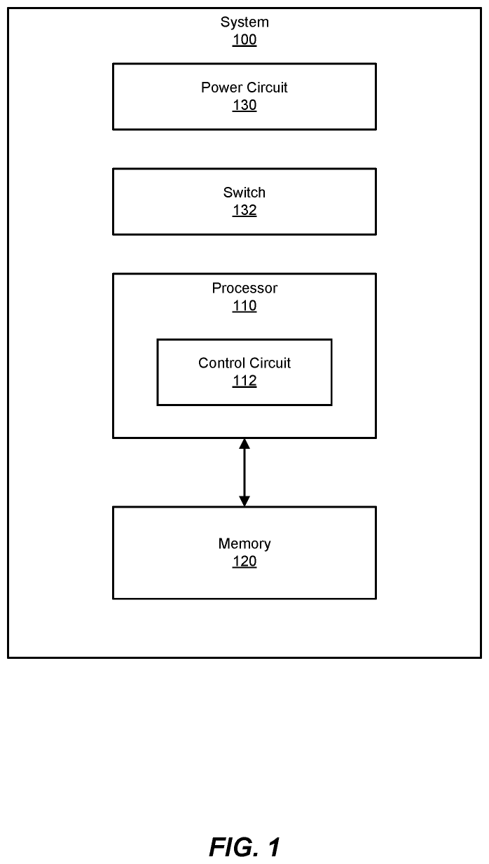

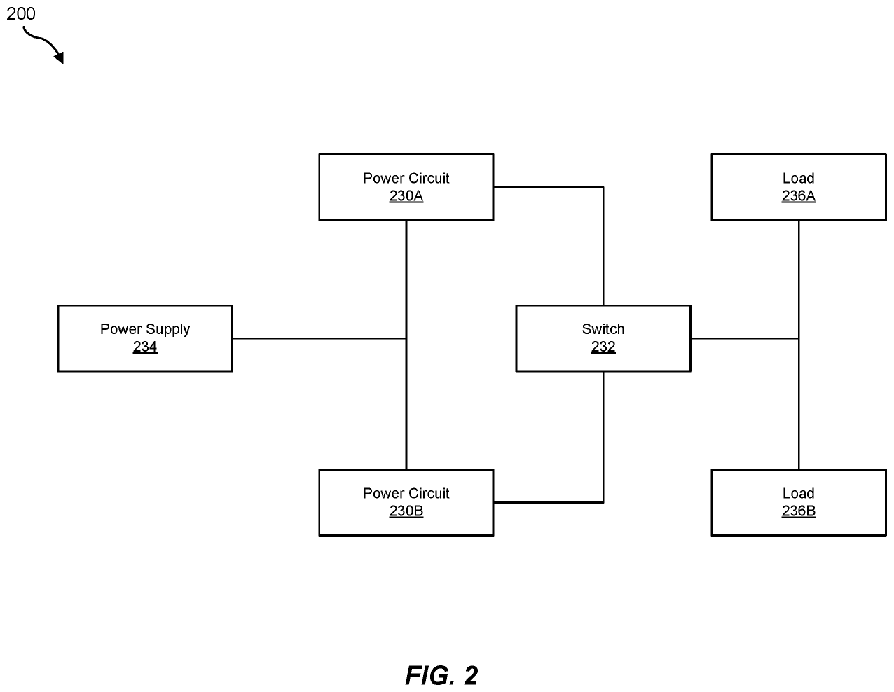

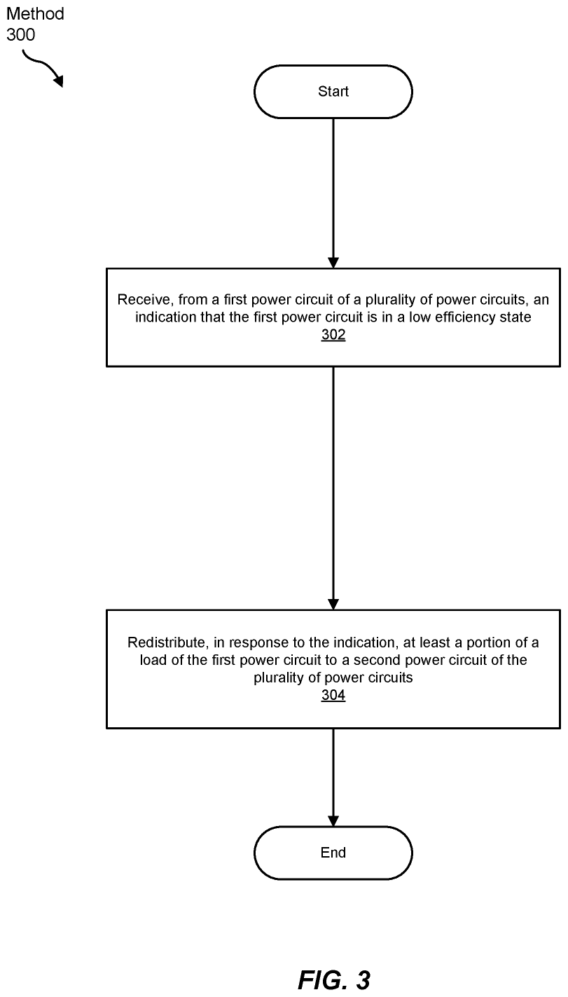

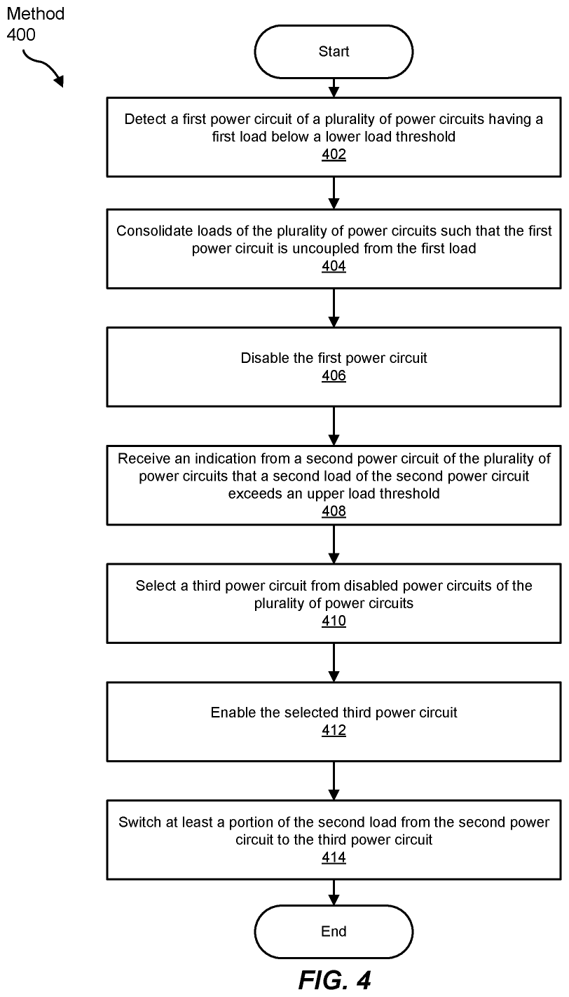

The following will provide, with reference to FIGS. 1-4, detailed descriptions of detecting, communicating, and responding to low efficiency power states. Detailed descriptions of example systems and circuits will be provided in connection with FIGS. 1 and 2. Detailed descriptions of corresponding methods will also be provided in connection with FIGS. 3 and 4.

FIG. 1 is a block diagram of an example system 100 for detecting low efficiency power states. System 100 corresponds to a computing device, such as a desktop computer, a laptop computer, a server, a tablet device, a mobile device, a smartphone, a wearable device, an augmented reality device, a virtual reality device, a network device, and/or an electronic device. As illustrated in FIG. 1, system 100 includes one or more memory devices, such as memory 120. Memory 120 generally represents any type or form of volatile or non-volatile storage device or medium capable of storing data and/or computer-readable instructions. Examples of memory 120 include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, and/or any other suitable storage memory.

As illustrated in FIG. 1, example system 100 includes one or more physical processors, such as processor 110. Processor 110 generally represents any type or form of hardware-implemented processing unit capable of interpreting and/or executing computer-readable instructions. In some examples, processor 110 accesses and/or modifies data and/or instructions stored in memory 120. Examples of processor 110 include, without limitation, chiplets (e.g., smaller and in some examples more specialized processing units that can coordinate as a single chip), microprocessors, microcontrollers, Central Processing Units (CPUs), graphics processing units (GPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, graphics processing units (GPUs), portions of one or more of the same, variations or combinations of one or more of the same, and/or any other suitable physical processor.

As further illustrated in FIG. 1, system 100 includes a power circuit 130 and a switch 132, and processor 110 includes a control circuit 112. Power circuit 130 can correspond to any power delivery network and/or circuit thereof, such as one or more voltage regulators. Switch 132 can correspond to any circuit, such as one or more power multiplexers, capable of taking one or more power inputs and directing them to desired outputs or loads (e.g., components). Although not shown in FIG. 1, power circuit 130 can be connected to switch 132 in various combinations. In some implementations, power circuit 130 can observe and communicate with control circuit 112, such as report on its own load conditions to control circuit 112, for instance to report when it enters a low efficiency state.

Control circuit 112 corresponds to one or more controllers that can control switch 132 to consolidate or otherwise redistribute loads of power circuit 130 in response to communications from power circuit 130. Control circuit 112 can also enable and/or disable power circuit 130 as needed.

FIG. 2 illustrates a system 200 that can correspond to system 100. FIG. 2 includes a power supply 234, a power circuit 230A corresponding to an iteration of power circuit 30, a power circuit 230B corresponding to another iteration of power circuit 30, a switch 232 corresponding to switch 32, a load 236A, and a load 236B. Power supply 234 can correspond to one or more power supply circuits connected to a power source, such as AC, battery, USB-C, etc. Load 236A and load 236B can each correspond to one or more components receiving power from power supply 234 via power circuit 230A and/or power circuit 230B. Although not shown in FIG. 2, a control circuit (e.g., control circuit 112) can be connected to power circuit 230A, power circuit 230B, and switch 232.

In one example, power circuit 230A can supply power to load 236A and power circuit 230B can supply power to load 236B. The control circuit can enter regulator shedding (e.g., disabling of voltage regulators) to improve efficiency in certain cases. Power circuit 230B can enter a low efficiency state, for example when power circuit 230B outputs too low of a current, power circuit 230B can operate inefficiently. Load 236B can enter a low power state or have a light workload such that it draws less current from power circuit 230B. Power circuit 230B can detect entering the low efficiency state, for example, by detecting that its current output is below a current threshold. The current threshold can correspond to when power circuit 230B operates below a desired efficiency and can be dynamically determined or predetermined (e.g., through empirical analysis of system 200).

After detecting that its current output is below the current threshold, power circuit 230B can send an indication of being in the low efficiency state to the control circuit. To improve efficiency, the control circuit can consolidate loads such that power circuit 230B, in its low efficiency state, is not used. The control circuit can select another power circuit that is appropriate to power load 236B, for example based on matching voltage rails with power circuit 230B, and having capacity for load 236B. The control circuit can select power circuit 230A, which in some examples can be an always-on power circuit that is not disabled.

After selecting the appropriate power circuit (e.g., power circuit 230A), the control circuit can switch, using switch 232, load 236B to power circuit 230A, thereby uncoupling load 236B from power circuit 230B. The control circuit can disable power circuit 230B, improving efficiency by avoiding usage of power circuit 230B in the low efficiency state, while still providing power as needed to load 236B.

In some examples, the control circuit can exit regulator shedding. For example, power circuit 230A can enter a low efficiency state. As a total load of power circuit 230A (e.g., load 236A and load 236B) increases (e.g., towards a maximum stable load for power circuit 230A), an efficiency of power circuit 230A decreases. For example, load 236B can exit a low power state or otherwise have an increase in its workload. Power circuit 230A can detect entering the low efficiency state by detecting, for example, detecting its load exceeding an upper load threshold. The upper load threshold can correspond to an undesired drop in efficiency as load increases, and can be dynamically determined or predetermined. Power circuit 230A can communicate to the control circuit an indication of being in the low efficiency state. The control circuit can redistribute at least a portion of the load (e.g., load 236B) of power circuit 230A such that the load is below the upper load threshold and power circuit 230A is no longer in the low efficiency state.

The control circuit can select an appropriate power circuit to redistribute the portion of the load (e.g., based on matching voltage rails with power circuit 230A). In some examples, the control circuit can select a power circuit based on available capacity for the portion of the load. In some examples, (e.g., if the enabled power circuits do not have such capacity), the control circuit can select a power circuit from disabled power circuits. In some examples, the control circuit can select a power circuit that was previously coupled to the portion of the loads. For instance, based on one or more of these factors, the control circuit can select power circuit 230B.

As power circuit 230B is disabled, the control circuit can enable power circuit 230B. The control circuit can switch, using switch 232, load 236B to power circuit 230B, reducing the total load of power circuit 230A such that power circuit 230A is no longer in the low efficiency state.

FIG. 2 illustrates a simplified example. In other examples, additional components (e.g., additional iterations of power supplies, power circuits, switches, loads, etc.) can be included and managed as described herein.

FIG. 3 is a flow diagram of an exemplary computer-implemented method 300 for detecting low efficiency power states. The steps shown in FIG. 3 can be performed by any suitable computer-executable code and/or computing system, including the system(s) illustrated in FIGS. 1 and/or 2. In one example, each of the steps shown in FIG. 3 represent an algorithm whose structure includes and/or is represented by multiple sub-steps, examples of which will be provided in greater detail below.

As illustrated in FIG. 3, at step 302 one or more of the systems described herein receive, from a first power circuit of a plurality of power circuits, an indication that the first power circuit is in a low efficiency state. For example, power circuit 130 can send an indication of being in a low efficiency state to control circuit 112. Control circuit 112 can receive indications from any number of power circuits 130.

The systems described herein can perform step 302 in a variety of ways. In one example, the indication can be sent in response to detecting the load exceeding an upper load threshold. In some examples, the upper load threshold can be dynamically determined. In some examples, the upper load threshold can be predetermined.

In other examples, the indication is in response to a current output of the first power circuit falling below a current threshold. In some examples, the current threshold can be dynamically determined. In some examples, the current threshold can be predetermined.

At step 304 one or more of the systems described herein redistribute, in response to the indication, at least a portion of a load of the first power circuit to a second power circuit of the plurality of power circuits. For example, control circuit 112 can redistribute load for power circuits 130 using switch 132.

The systems described herein can perform step 304 in a variety of ways. In one example, control circuit 112 can redistribute at least the portion of the load of the first power circuit by selecting the second power circuit based on matching voltage rails with the first power circuit, enabling the second power circuit, and switching at least the portion of the load of the first power circuit to the second power circuit. In some examples, control circuit 112 can select the second power circuit from disabled power circuits. In some examples, the first power circuit corresponds to an always-on power circuit configured to communicate with the control circuit.

In some examples, control circuit 112 can redistribute at least the portion of the load of the first circuit by switching the load of the first power circuit to the second power circuit and disabling the first power circuit.

FIG. 4 is a flow diagram of an exemplary computer-implemented method 400 for detecting low efficiency power states. The steps shown in FIG. 4 can be performed by any suitable system and/or circuit, including the system(s) illustrated in FIGS. 1 and/or 2. In one example, each of the steps shown in FIG. 4 represent an algorithm whose structure includes and/or is represented by multiple sub-steps, examples of which will be provided in greater detail below.

As illustrated in FIG. 4, at step 402 one or more of the systems described herein detect a first power circuit of a plurality of power circuits having a first load below a lower load threshold. For example, control circuit 112 can detect power circuit 130 having a load below a lower load threshold based on a communication from power circuit 130.

At step 404 one or more of the systems described herein consolidate loads of the plurality of power circuits such that the first power circuit is uncoupled from the first load. For example, control circuit 112 can switch, using switch 132, the load from power circuit 130 to another power circuit (e.g., another iteration of power circuit 130).

The systems described herein can perform step 404 in a variety of ways. In one example, control circuit 112 can select, from the plurality of power circuits, a fourth power circuit based on matching voltage rails with the first power circuit, and switch the first load from the first circuit to the selected fourth power circuit.

At step 406 one or more of the systems described herein disable the first power circuit. For example, control circuit 112 can disable power circuit 130.

The systems described herein can perform step 406 in a variety of ways. In one example, control circuit 112 can disable power circuit 130 by power gating power circuit 130 itself. In other examples, control circuit 112 can place power circuit 130 in a dormant or inactive state. In yet other examples, power circuit 130 can become dormant in response to being uncoupled from a load.

At step 408 one or more of the systems described herein receive an indication from a second power circuit of the plurality of power circuits that a second load of the second power circuit exceeds an upper load threshold. For example, control circuit 112 can receive from a power circuit (e.g., power circuit 130) an indication that its load exceeds an upper load threshold.

The systems described herein can perform step 408 in a variety of ways. In one example, the power circuit can be the same power circuit used for uncoupling the power circuit referenced in step 404. In other examples, a different power circuit can communicate its low efficiency state (e.g., that its load exceeds the upper load threshold).

At step 410 one or more of the systems described herein select a third power circuit from disabled power circuits of the plurality of power circuits. For example, control circuit 112 can select another power circuit (e.g., another iteration of power circuit 130) from disabled power circuits.

The systems described herein can perform step 410 in a variety of ways. In one example, control circuit 112 can select the third power circuit is based on matching voltage rails with the second power circuit. Although control circuit 112 can select from disabled power circuits, in other examples, control circuit 112 can select from any available power circuit with a matching voltage rail. The available power circuit can have capacity for taking some or all of the load from the power circuit in the low efficiency state, and in some examples disabled power circuits can be available power circuits.

At step 412 one or more of the systems described herein enable the selected third power circuit. For example, control circuit 112 can enable the selected power circuit.

The systems described herein can perform step 414 in a variety of ways. In one example, control circuit 112 can restore power to the power circuit, for instance when the disabled power circuit was power gated. In other examples, control circuit 112 can activate the selected power circuit. In some examples, the selected power circuit can be enabled as part of a process for switching a load to the selected power circuit.

At step 414 one or more of the systems described herein switch at least a portion of the second load from the second power circuit to the third power circuit. For example, control circuit 112 can switch, using switch 132, at least a portion of the load to the selected power circuit.

The systems described herein can perform step 414 in a variety of ways. In one example, the portion of the load can correspond to a load previously switched from the selected power circuit such that this portion of the load is being switched back to its original power circuit.

As detailed above, there are many power regulators on a laptop. Shedding (e.g., disabling or deactivating) regulators that are operating in light load conditions to decrease driver and controller losses, and consolidating the loads to other power rails (e.g., always-on power rails) can improve system power efficiency and extend battery lifetime of laptop devices.

Although regulator shedding provides improved efficiency and power performance, in some cases it may be desirable to reenable the disabled regulators. The systems and methods described herein provide a form of communication between the always-on power regulator and the SoC or controller where the power regulator can inform the SoC that its load has crossed a certain threshold. This can trigger the SoC to reassess its workload and re-enable the dormant/inactive regulators accordingly. The systems and methods described herein can advantageously provide a reliable way to reenable power regulators without impacting performance and functionality.

As detailed above, the circuits, devices and systems described and/or illustrated herein broadly represent any type or form of computing device or system capable of executing computer-readable instructions. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the modules and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), systems on a chip (SoCs), digital signal processors (DSPs), Neural Network Engines (NNEs), accelerators, graphics processing units (GPUs), portions of one or more of the same, variations or combinations of one or more of the same, or any other suitable physical processor.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a control circuit configured to:
receive, from a first power circuit of a plurality of power circuits, an indication that the first power circuit is in a low efficiency state; and
redistribute, in response to the indication, at least a portion of a load of the first power circuit to a second power circuit of the plurality of power circuits.

2. The device of claim 1, wherein:
the indication is in response to detecting the load exceeding an upper load threshold; and
the control circuit is configured to redistribute at least the portion of the load of the first power circuit by:
selecting the second power circuit based on matching voltage rails with the first power circuit;
enabling the second power circuit; and
switching at least the portion of the load of the first power circuit to the second power circuit.

3. The device of claim 2, wherein the control circuit is further configured to select the second power circuit from disabled power circuits of the plurality of power circuits.

4. The device of claim 2, wherein the first power circuit corresponds to an always-on power circuit configured to communicate with the control circuit.

5. The device of claim 2, wherein the upper load threshold is dynamically determined.

6. The device of claim 2, wherein the upper load threshold is predetermined.

7. The device of claim 1, wherein:
the indication is in response to a current output of the first power circuit falling below a current threshold; and
the control circuit is configured to redistribute at least the portion of the load of the first circuit by:
switching the load of the first power circuit to the second power circuit; and
disabling the first power circuit.

8. A system comprising:
a plurality of power circuits; and
a control circuit configured to:
receive, from a first power circuit of the plurality of power circuits, an indication that the first power circuit is in a low efficiency state;
select a second power circuit of the plurality of power circuits; and
switch at least a portion of a load of the first power circuit to the second power circuit.

9. The system of claim 8, wherein the control circuit is configured to select the second power circuit based on matching voltage rails of the first and second power circuits.

10. The system of claim 8, further comprising at least one switch for switching the load between the first and second power circuits.

11. The system of claim 10, wherein the at least one switch corresponds to a multiplexer.

12. The system of claim 8, wherein the first power circuit is configured to send the indication in response to detecting the load exceeding an upper load threshold.

13. The system of claim 12, wherein the control circuit is configured to:
select the second power circuit from disabled power circuits of the plurality of power circuits; and
enable the second power circuit.

14. The system of claim 12, wherein the upper load threshold is dynamically determined.

15. The system of claim 12, wherein the upper load threshold is predetermined.

16. The system of claim 8, wherein:
the first power circuit is configured to send the indication in response to detecting that a current output of the first power circuit is below a current threshold; and
the control circuit is further configured to:
switch the load of the first power circuit to the second power circuit; and
disable the first power circuit.

17. The system of claim 16, wherein the current threshold is dynamically determined or predetermined.

18. A method comprising:
detecting a first power circuit of a plurality of power circuits having a first load below a lower load threshold;
consolidating loads of the plurality of power circuits such that the first power circuit is uncoupled from the first load;
disabling the first power circuit;
receiving an indication from a second power circuit of the plurality of power circuits that a second load of the second power circuit exceeds an upper load threshold;
selecting a third power circuit from disabled power circuits of the plurality of power circuits;
enabling the selected third power circuit; and
switching at least a portion of the second load from the second power circuit to the third power circuit.

19. The method of claim 18, wherein consolidating the plurality of power circuits further comprises:
selecting, from the plurality of power circuits, a fourth power circuit based on matching voltage rails with the first power circuit; and
switching the first load from the first circuit to the selected fourth power circuit.

20. The method of claim 18, wherein selecting the third power circuit is based on matching voltage rails with the second power circuit.
